(19) United States
(12) Patent Application Publication
(10) Pub. No.: US 2005/0184884 A1
(43) Pub. Date: Aug. 25, 2005

(54) Spatial information input apparatus and method for recognizing information-completion signal from a plurality of concurrent spatial motions

(75) Inventors: Sung-cheol Kim, Yongin-si (KR); Sang-goog Lee, Anyang-si (KR); Jun-il Sohn, Yongin-si (KR); Sung-jung Cho, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/043,090

(22) Filed: Jan. 27, 2005

(30) Foreign Application Priority Data
Feb. 25, 2004 (KR) 2004-12541

(51) Int. Cl. H03K 17/94

(52) U.S. Cl. 341/22; 345/168

(57) ABSTRACT

A spatial information input apparatus and method are provided. The apparatus includes: a motion detecting unit which detects motions of respective parts of the body as predetermined motion signals; and a motion-signal processing unit which outputs the motion signals, which are substantially concurrently detected, as effective motion signals having specific functions.

### BACKGROUND OF THE INVENTION

This application claims the priority of Korean Patent Application No. 2004-12541, filed on Feb. 25, 2004, in the Korean Intellectual Property Office, the disclosure of which is incorporated herein in its entirety by reference.

1. Field of the Invention

The present invention relates to a spatial information input apparatus and method for detecting motion of a human and utilizing the detected human motion as an effective signal, and more particularly, to a spatial information input apparatus and method in which when a plurality of concurrent spatial motions is detected, an information-completion signal is recognized after a predetermined duration starting from the detection time of an effective signal.

2. Description of the Related Art

One of most important factors needed for effectively utilizing a computer is an interface between the computer and a user of the computer. As representative user interfaces, there are a keyboard and a mouse. In addition to the keyboard and the mouse, a new type of input unit is increasingly required.

Specifically, in addition to a conventional finger-touching input method, a spatial information input apparatus is being constantly developed, together with the development of a computer game, to utilize spatial motion of a specific part of a human body such as hands, thumbs or fingers, as an input signal. Further, there is also an example in which the spatial information input apparatus is combined with a learning computer for inducing an infant's interest.

FIG. 1 illustrates a conventional spatial information input apparatus in which finger motion is used as an input signal. Hereinafter, the finger motion having the purpose of inducing any function is called a “click”, and a signal generated by the click is called “information-completion signal.” Acceleration sensors 12a of the motion detecting unit 12 sense the acceleration of each of the fingers 11. Multipliers 13a of a regularizing unit 13 multiply an appropriate weighted value, which is differently allocated to each finger, with a magnitude of the acceleration of each of the fingers, thereby regularizing the magnitude of the acceleration. An Analog-to-Digital Converter (ADC) 14 converts a regularized analogous acceleration signal into a digital motion signal. An effective-signal deciding unit 15 allocates a bit of ‘1’ to a motion zone, having a value greater than a critical voltage value, among the acceleration signals, and allocates a bit of ‘0’ to a motion zone having less than the critical voltage value. Accordingly, a computer receives the motion signal from the spatial information input apparatus to recognize the bit of ‘1’ as the effective signal.

In the meantime, in cases where a subsequent effective signal is detected for a predetermined duration starting from the detection time of the effective signal while one of the fingers 11 is in continuous motion or fingers different from one another are in sequential motions, a time-difference comparator 16 outputs only a firstly sensed signal as the effective signal. For example, in a case where an index finger and a middle finger are allowed to be in sequential motion in order to detect a signal 1 and a signal 2 as shown in FIG. 2A, the signal 1 and the signal 2 are respectively outputted from the time-difference comparator 16 as the effective signals, due to the signal 2 that is detected after a predetermined duration Te starting from the detection time of the signal 1.

At this time, the signal 1 and the signal 2 are data streams of the bits ‘0’ and ‘1’ passed through the effective-signal deciding unit 15. Since the acceleration magnitude of each of the fingers is regularized, the duration Te for which the effective signal is detected will be substantially identical with every finger. Further, a detection duration T of the motion signal is determined with regard to maximal times per second at which humans can generate the spatial motion of a finger. For example, it is difficult for humans to continuously move a finger at more than five times per second. Accordingly, the detection duration T is generally limited to above 200 ms. At this time, on the assumption that an acceleration curve based on the motion is a regular sinusoidal curve, a positive portion of the acceleration curve is recognized as an ineffective signal due to the recognition of only a signal having more than a predetermined voltage as the effective signal, thereby generally providing an asymmetric result of the effective-signal detection duration Te to the ineffective-signal detection duration Ti.

In the meantime, as shown in FIG. 2B, in a case where the signal 1 begins to be detected at the time of t1, and the signal 2 begins to be detected at the time of t2 before the duration Te of signal 1 expires, the time-difference comparator 16 finally outputs only the signal 1 as the effective signal without regard to the signal 2 detected at the time of t2. At this time, since even the concurrent motions substantially have a difference in time to some degree, the signals as shown FIG. 2B are detected.

However, the conventional spatial information input apparatus has a drawback in that the concurrent motions of a plurality of fingers cannot be provided with any function since only an initially detected motion signal among several concurrent motions of fingers is recognized as the effective signal. Specifically, a game player utilizing fingers is remarkably required for providing the concurrent motions of fingers with a specific function in order to perform a maximal function with the limited number of sensors.

### SUMMARY OF THE INVENTION

An exemplary embodiment of the present invention provides a spatial information input apparatus and method in which when a plurality of concurrent spatial motions of fingers are detected, the spatial motions are finally recognized after a predetermined duration starting from the detection time of an initial motion, thereby recognizing the spatial motions as effective motions.

Also, an exemplary embodiment of the present invention provides a spatial information input apparatus and method in which a plurality of concurrent spatial motions of fingers is recognized as effective motions, thereby providing more various functions.

Consistent with an aspect of the present invention, there is provided a spatial information input apparatus including: a motion detecting unit which detects motions of respective parts of the body as predetermined motion signals; and a motion-signal processing unit which outputs the motion signals, which are substantially concurrently detected, as effective motion signals having specific functions.

At this time, the motion-signal processing unit can recognize that the motion signals are substantially concurrently detected, when an effective motion signal is detected at a first part of the plurality of parts of the body, and then an effective motion signal is detected at a second part of the plurality of parts of the body for a predetermined duration within a motion-signal detection period.

The effective motion signals are detected when the motion signals exceed a critical value, and the predetermined duration is a duration for which the effective motion signals are continuously detected.

Further, the motion detecting unit can be comprised of acceleration sensors for detecting variations of acceleration at each of the plurality of parts of the body.

Further, the motion-signal processing unit includes: a regularizing unit which regularizes the motion signals depending on motion characteristics of each of the plurality of parts of the body; an A/D converting unit which converts the regularized motion signals into digital motion signals; an effective-signal deciding unit which decides a signal having a value greater than a critical value, among the converted motion signals, as an effective motion signal; and a signal recognizing unit which recognizes that a first and a second motion signal are substantially concurrently detected, when an effective signal of the first motion signal is detected and then, at least one effective signal of the second motion signal is detected for a predetermined duration less than a maintenance duration of the effective signal of the first motion signal.

At this time, the effective-signal deciding unit samples the converted motion signals every sampling period, and allocates a bit of ‘1’ when a magnitude of a sampled signal is greater than the critical value, and allocates a bit of ‘0’ when the magnitude of a sampled signal is not greater than the critical value. Further, the signal recognizing unit comprises a memory unit which stores information on whether there is the effective signal in the first motion signal and the second motion signal, every motion signal and every sampling period, for a predetermined duration starting from the time when the effective signal of the first motion signal is detected, and wherein the signal recognizing unit outputs the stored information as a data stream representing a specific function after the predetermined duration expires.

Consistent with another aspect of the present invention, there is provided a spatial information input method including: detecting respective motions of a plurality of predetermined parts of a body as predetermined motion signals; and outputting the motion signals, which are substantially concurrently detected, as effective signals having specific functions.

At this time, the outputting of the motion signals includes: regularizing the motion signals depending on motion characteristics of each of the plurality of predetermined parts of the body; converting the regularized motion signals into digital motion signals; deciding a motion signal having a value greater than a critical value, among the converted digital motion signals, as an effective motion signal; and recognizing that a first and a second motion signal are substantially concurrently detected, when an effective signal of the first motion signal is detected and then, at least one effective signal of the second motion signal is detected for a predetermined duration less than a maintenance duration of the effective signal of the first motion signal.

Further, the recognizing of the concurrent detection includes: storing information on whether there is the effective signal of a first and a second motion signal, every motion signal and every sampling period, for a predetermined duration starting from the time when the effective signal of the first motion signal is detected; and outputting the stored information as a data stream representing a specific function after the predetermined duration expires.

Consistent with another aspect of the present invention, there is provided a computer-readable recording medium which records program for executing a spatial information input method.

In the meantime, the inventive spatial information input apparatus and method can be also applied to the recognition of finger motion as effective information.

### BRIEF DESCRIPTION OF THE DRAWINGS

The above and other features and advantages of the present invention will become more apparent by describing in detail exemplary embodiments thereof with reference to the attached drawings in which:

FIG. 1 is a view illustrating a construction of a conventional spatial information input apparatus;

FIGS. 2A and 2B are examples of digital signal waveforms that are detected at a spatial information input apparatus of FIG. 1;

FIG. 3 is a view illustrating a construction of a spatial information input apparatus consistent with an exemplary embodiment of the present invention;

FIG. 4 is a view illustrating a state in which a hand wears a spatial information input apparatus of FIG. 3 in a hand-in-glove manner;

FIGS. 5A and 5B are examples of motion signal waveforms for describing the deciding of an effective signal consistent with an exemplary embodiment of the present invention;

FIG. 6 is an example of a function allocation table depending on a detection pattern of a finger-motion signal consistent with an exemplary embodiment of the present invention; and

FIG. 7 is a flowchart illustrating a spatial information input method consistent with an exemplary embodiment of the present invention.

### DETAILED DESCRIPTION OF THE INVENTION

The invention can also be embodied as computer-readable code on a computer-readable recording medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, optical data storage devices, and carrier waves (such as data transmission through the Internet). The computer-readable recording medium can also be distributed over network coupled computer systems so that the computer-readable code is stored and executed in a distributed fashion. Also, functional programs, codes, and code segments for accomplishing the present invention can be easily construed by programmers skilled in the art to which the present invention pertains.

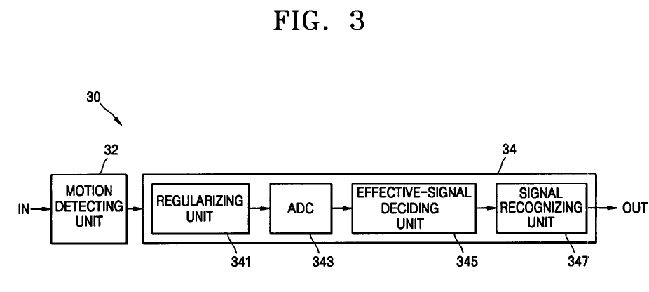

FIG. 3 is a view illustrating a construction of a spatial information input apparatus consistent with an exemplary embodiment of the present invention.

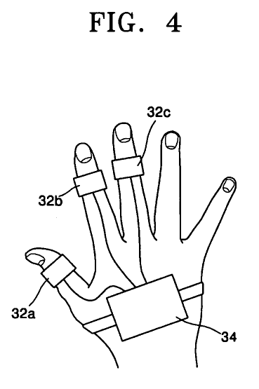

The spatial information input apparatus 30 is comprised of acceleration sensors allocated to each finger, and includes a motion detecting unit 32 for detecting each finger motion; and a signal processing unit 34 for outputting a signal having a specific function depending on a pattern of the detected finger motion. Further, as shown in FIG. 4, the motion detecting unit 32 includes a plurality of sensors 32a, 32b and 32c, which are respectively attached to a thumb finger, an index finger and a middle finger to detect the motions of each of the fingers. The signal processing unit 34 is disposed on the back of the hand to be electrically connected with each of the sensors 32a, 32b and 32c in a wire or wireless network. Further, the inventive spatial information input apparatus 30 is provided in a hand-in-glove manner. However, the inventive spatial information input apparatus 30 can be attached to a foot, head, arm, leg and/or the like in addition to the hand, which are parts of the body that are used as the basis of motion information.

At this time, it does not matter whatever is used as the sensors 32a, 32b and 32c as long as it detects the finger motion to output the detected finger motion as a predetermined motion signal. For example, the degree of the finger motion can be sensed through a variation of acceleration, a variation of angular velocity, a variation of resistance, a variation of capacitance, a variation of magnetic field, a direction of magnetic field or a variation of the number of pulses. For this, the motion detecting unit 32 can be comprised of a Micro ElectroMechanical System (MEMS) inertia sensor for sensing the variation of acceleration or the variation of angular velocity; a variable resistance sensor for sensing the variation of resistance; a variable capacitance sensor for sensing the variation of capacitance; a magnetic sensor for sensing the variation or the direction of magnetic field; or a rotary encoder-typed sensor for sensing the variation of the number of pulses.

A regularizing unit 341 can be comprised of multipliers (not shown) for multiplying a predetermined weighted value with an inputted sense signal so as to regularize the inputted sense signal. That is, in a case where the sensors 32a, 32b and 32c are respectively attached to the thumb finger, the index finger and the middle finger as shown in FIG. 4, the amounts of finger motion are different from one another when each of the fingers is clicked. Therefore, the motion-sensed results need to be regularized such that only a magnitude-varied component is detected from the motion-sensed results by characteristic amount. For this, a weighted value, which is multiplied with the motion-sensed results of the thumb finger, can be set larger than a weighted value, which is multiplied with the motion-sensed results of other fingers. As described above, the weighted value is empirically set depending on the motion degree of each of the fingers, and may be particularly preset through experimentation.

An Analog-to-Digital Converter (ADC) 343 converts an analogous motion signal, which is regularized in the regularizing unit 341, into a digital motion signal. At this time, the ADC 343 is disposed at the rear of the regularizing unit 341, but it does not matter that the ADC 343 is disposed at the front of the regularizing unit 341. The ADC 343 can be also omitted in a case where the signal detected in the motion detecting unit 32 is in a digital format.

An effective-signal deciding unit 345 recognizes only a motion signal, which has a value greater than a critical value, among the detected motion signals, as the effective signal. That is, even though a finger is not in motion, minute motion can be always sensed. Furthermore, when any finger is in motion, other fingers adjacent to the one finger in motion are in a little motion along with the one finger in motion, in view of a finger structure. Therefore, only a significant motion needs to be recognized as the effective signal without regard to unintentional motion. Accordingly, the effective-signal deciding unit 345 recognizes only the signal having a value greater than the critical value as the significant effective signal to exclude the unintentional motion.

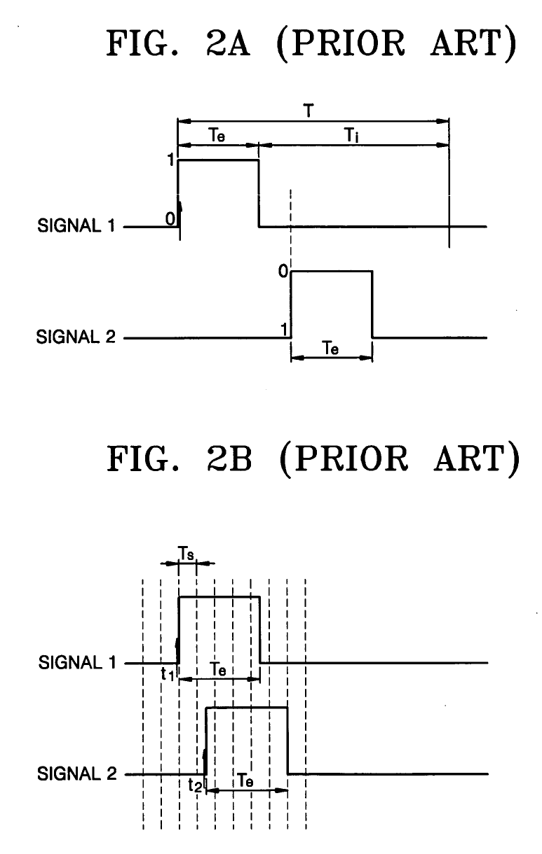

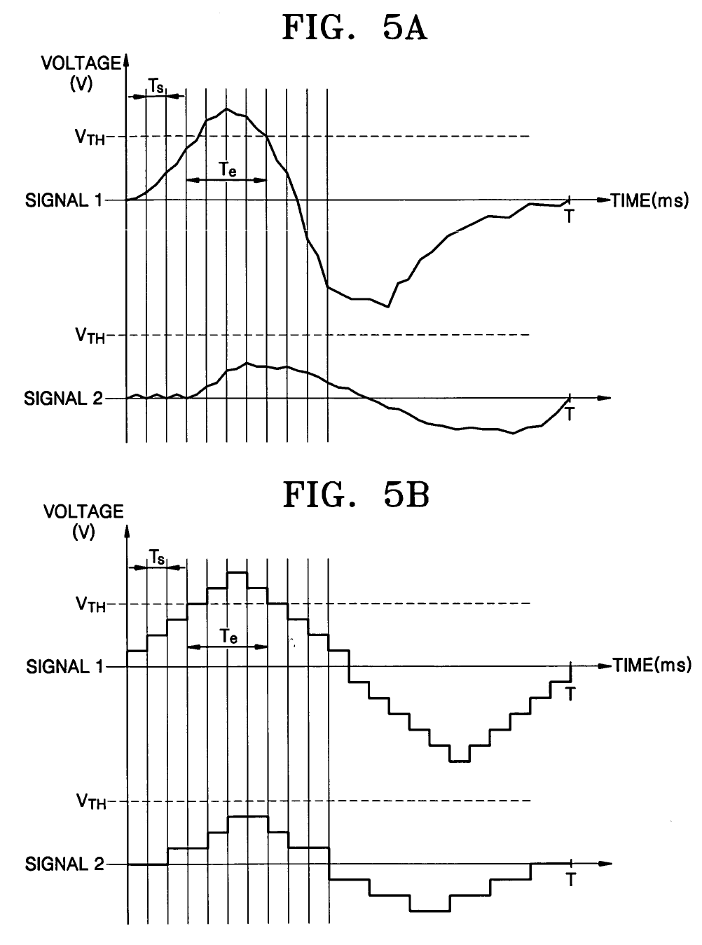

FIG. 5A illustrates a time-dependent variation of the analogous motion signal outputted from the motion detecting unit 32 and the regularizing unit 341, and FIG. 5B illustrates a time-dependent variation of the digital motion signal corresponding to the analogous motion signal of FIG. 5A. Since a signal 1 exceeds a threshold voltage Vth for a duration Te, the signal 1 is recognized as an effective signal during the duration Te. However, a signal 2 does not exceed the threshold voltage Vth during the duration Te, the signal 2 is recognized as an ineffective signal. At this time, the effective-signal deciding unit 345 allocates a bit of ‘1’ to the motion signal having more than the threshold voltage Vth and a bit of ‘0’ to other motion signals to generate motion signal streams represented by ‘1’ and ‘0’ as shown in FIG. 2. At this time, when the effective-signal detection duration Te is set within a range of 50 ms to 100 ms at a detection period T of 200 ms, a click input speed and a recognition ratio of the motion signal are all better.

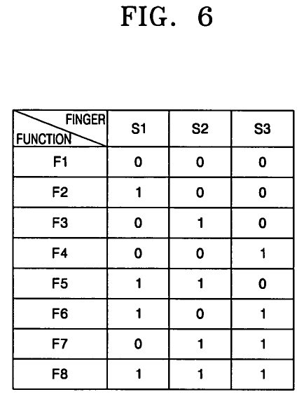

The signal recognizing unit 347 outputs a predetermined function signal depending on the detection pattern, so as to provide functions corresponding to the detection patterns of the motion signals of the three fingers. FIG. 6 is an example of a function allocation table depending on the detection pattern of the finger-motion signal consistent with an exemplary embodiment of the present invention. The signal recognizing unit 347 transmits three bits of a data stream (S1-S2-S3) to the computer (not shown) at a predetermined time interval. The computer is controlled under the control of a processor to change a construction of an interface screen or perform a specific operation on the basis of the outputted data stream.

In other words, the signal recognizing unit 347 allocates the bit of ‘1’ or ‘0’ to each of the fingers depending on existence or not of the effective signal, which is detected during the effective-signal detection duration Te of the motion signal, to generate three bits of a data stream (S1-S2-S3). Further, the signal recognizing unit 347 can provide eight different functions (F1 to F8) depending on the detection patterns in which the motion signals of the three fingers such as the thumb finger (S1), the index finger (S2) and the middle finger (S3) are detected during the effective-signal detection duration Te. For example, in a case where the data stream (S1-S2-S3) is represented by ‘110’, the signal recognizing unit 347 recognizes that the motions of the thumb finger (S1) and the index finger (S2) are concurrently detected during the effective-signal detection duration Te. At this time, whether or not the motion signal is the effective signal is determined depending on whether or not a rising edge of a motion signal stream is detected within the effective-signal detection duration Te.

For this, the signal recognizing unit 347 provides an internal buffer to store other signals, which are detected during the effective-signal detection duration Te starting from the detection time of an initial effective signal, and the signal recognizing unit 347 outputs the three bits of a data stream of FIG. 6 after the effective-signal detection duration Te expires.

For example, in FIG. 2B, if the rising edge of the data stream of the signal 1 is detected at the time of t1, a data stream of (1, 1, 1, 1) is stored in the first buffer depending on a sampling period Ts until the time (t1+Te), and a data stream of (0, 0, 1, 1) is stored in a second buffer during the duration of t1 to (t1+Te) for the data stream of the signal 2. Since other signals are no longer detected during the duration t1 to (t1+Te), the signal recognizing unit 347 finally outputs ‘110’ at a sampling time soon after the time (t1+Te).

In the meantime, since the detection signal, which is detected after the effective-signal detection duration Te, is recognized as a sequential motion signal, the present invention regards the signal detected during the effective-signal detection duration Te as the concurrent-motion signal, but will also regards the motion signals, which are detected during the duration shorter than the effective-signal detection duration Te, as the concurrent-motion signal.

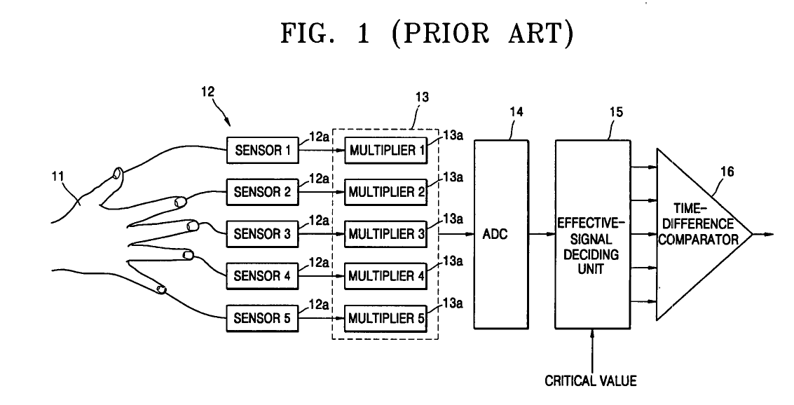

As described above, in case where different motion signals of fingers are detected within the effective signal detection duration Te, the conventional spatial information input apparatus of FIG. 1 has a drawback in that only a first detection signal is recognized as the effective signal and the concurrent-motion signal cannot be recognized as the effective signal because a subsequently selected signal is disregarded. However, consistent with an exemplary embodiment of the present invention, the concurrent detection of the motion signal can be performed by the signal recognizing unit 347. Accordingly, the concurrent motion is provided with the specific function, thereby providing more various functions.

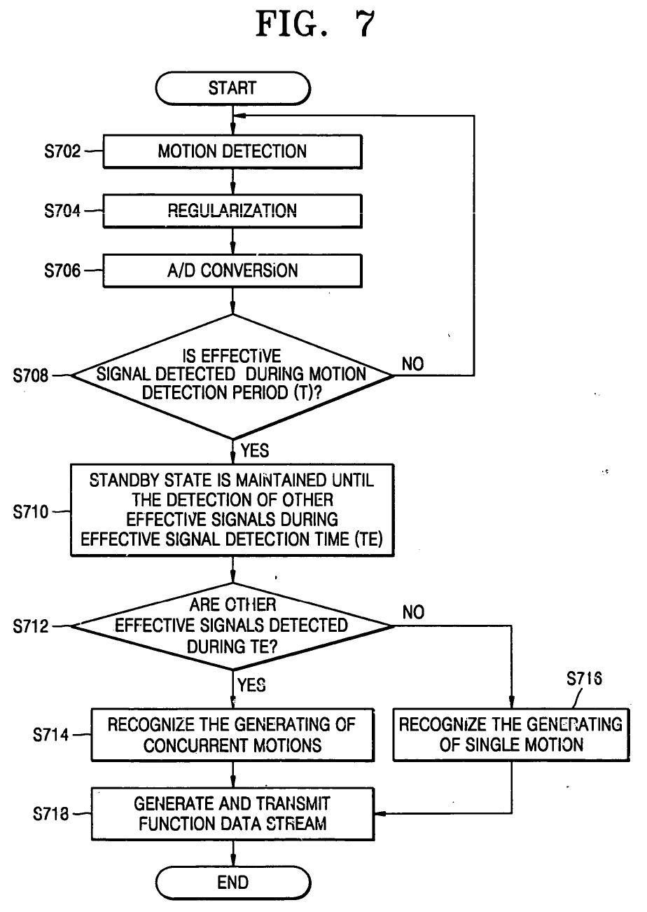

FIG. 7 is a flowchart illustrating a spatial information input method consistent with an exemplary embodiment of the present invention. The flowchart of FIG. 7 is described with reference to the spatial information input apparatus 30 of FIG. 3 as follows.

If the motion signals of the fingers are detected, regularized and digitally-converted in the motion detecting unit 32, the regularizing unit 341 and the ADC 343 (S702), (S704) and (S706), the effective-signal deciding unit 345 determines whether or not the effective signal is detected during the motion detection period T (S708). If it is determined that the effective signal is not detected, a standby state is maintained until the motion is detected (S702). If it is determined that the effective signal is detected, the standby state is maintained until other effective signals are detected (S710). At this time, the effective-signal deciding unit 345 decides the motion signal, which has more than the critical value during the duration Te, as the effective signal.

The signal recognizing unit 347 is in a standby state until other effective signals are detected during the effective-signal detection duration Te after the initial effective signal is detected at the time of t1. If the other effective signals are detected during the duration Te, the signal recognizing unit 347 recognizes that a motion of a corresponding effective signal and a motion of the initial effective signal are concurrently generated (S712), (S714). Otherwise, the signal recognizing unit 347 recognizes that only motion corresponding to the initial effective signal is generated (S712), (S716). Accordingly, the signal recognizing unit 347 finally generates three bits of a data stream having the specific functions (F1 to F8) as shown in FIG. 6 to transmit the generated data stream to an external computer (S718).

The embodiments of the present invention can be written as computer programs and can be implemented in general-use digital computers that execute the programs using a computer-readable recording medium. Examples of the computer-readable recording medium include magnetic storage media (e.g., ROM, floppy disks, hard disks, etc.), optical recording media (e.g., CD-ROMs, or DVDs), and storage media such as carrier waves (e.g., transmission through the Internet).

As described above, the exemplary embodiment of the present invention has an effect in that when the plurality of spatial motions of the fingers are detected, the spatial motions of the fingers are finally recognized after a predetermined duration starting from the detection time of the initial motion, thereby recognizing the plurality of concurrent motions of the fingers as the effective motion.

Further, an aspect of the present invention has an effect in that the plurality of concurrent motions of the fingers are recognized as the effective motions, thereby providing more various functions.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A spatial information input apparatus comprising:
a motion detecting unit which detects motions of a plurality of parts of a human body as predetermined motion signals; and
a motion-signal processing unit which outputs the motion signals, which are substantially concurrently detected, as effective motion signals having specific functions.

2. The apparatus of claim 1, wherein the motion-signal processing unit recognizes that the motion signals are substantially concurrently detected, when an effective motion signal is detected at a first part of the plurality of parts of the body, and then an effective motion signal is detected at a second part of the plurality of parts of the body for a predetermined duration within a motion-signal detection period.

3. The apparatus of claim 2, wherein the effective motion signals are detected when the motion signals exceed a critical value, and
wherein the predetermined duration is a duration for which the effective motion signals are continuously detected.

4. The apparatus of claim 1, wherein the motion detecting unit comprises acceleration sensors for detecting variations of acceleration at each of the plurality of parts of the body.

5. The apparatus of claim 1, wherein the motion-signal processing unit comprises:
a regularizing unit which regularizes the motion signals depending on motion characteristics of each of the plurality of parts of the body;
an Analog-to-Digital (A/D) converting unit which converts the regularized motion signals into digital motion signals;
an effective-signal deciding unit which decides a motion signal having a value greater than a critical value, among the converted motion signals, as an effective motion signal; and
a signal recognizing unit which recognizes that a first and a second motion signal are substantially concurrently detected, when an effective signal of the first motion signal is detected and then, at least one effective signal of the second motion signal is detected for a predetermined duration which is less than a maintenance duration of the effective signal of the first motion signal.

6. The apparatus of claim 5, wherein the effective-signal deciding unit samples the converted motion signals every sampling period, and allocates a bit of ‘1’ when a magnitude of a sampled motion signal is greater than the critical value, and allocates a bit of ‘0’ when the magnitude of a sampled motion signal is not greater than the critical value.

7. The apparatus of claim 5, wherein the signal recognizing unit comprises a memory unit which stores information on whether there is the effective signal in the first motion signal and the second motion signal, every motion signal and every sampling period, for a predetermined duration starting from the time when the effective signal of the first motion signal is detected, and
wherein the signal recognizing unit outputs the stored information as a data stream representing a specific function after the predetermined duration expires.

8. A spatial information input method comprising:
detecting respective motions of a plurality of predetermined parts of a body as predetermined motion signals; and
outputting the motion signals, which are substantially concurrently detected, as effective signals having specific functions.

9. The method of claim 8, wherein the outputting of the motion signals comprises:
regularizing the motion signals depending on motion characteristics of each of the plurality of predetermined parts of the body;
converting the regularized motion signals into digital motion signals;
deciding a motion signal having a value greater than a critical value, among the converted digital motion signals, as an effective motion signal; and
recognizing that a first and a second motion signal are substantially concurrently detected, when an effective signal of the first motion signal is detected, and then at least one effective signal of the second motion signal is detected for a predetermined duration less than a maintenance duration of the effective signal of the first motion signal.

10. The method of claim 9, wherein the recognizing of the concurrent detection comprises:
storing information on whether there is an effective signal of a first and a second motion signal, every motion signal and every sampling period, for a predetermined duration starting from the time when the effective signal of the first motion signal is detected; and
outputting the stored information as a data stream representing a specific function after the predetermined duration expires.

11. A computer-readable recording medium which records a program for executing a method comprising:
detecting respective motions of a plurality of predetermined parts of a body as predetermined motion signals; and
outputting the motion signals, which are substantially concurrently detected, as effective signals having specific functions.

12. The computer-readable recording medium according to claim 11, wherein the outputting of the motion signals comprises:
regularizing the motion signals depending on motion characteristics of each of the plurality of predetermined parts of the body;
converting the regularized motion signals into digital motion signals;
deciding a motion signal having a value greater than a critical value, among the converted digital motion signals, as an effective motion signal; and
recognizing that a first and a second motion signal are substantially concurrently detected, when an effective signal of the first motion signal is detected, and then at least one effective signal of the second motion signal is detected for a predetermined duration less than a maintenance duration of the effective signal of the first motion signal.

13. The computer-readable recording medium according to claim 12, wherein the recognizing of the concurrent detection comprises:
storing information on whether there is an effective signal of a first and a second motion signal, every motion signal and every sampling period, for a predetermined duration starting from the time when the effective signal of the first motion signal is detected; and
outputting the stored information as a data stream representing a specific function after the predetermined duration expires.

14. A spatial information input apparatus comprising:
a motion detecting unit which detects respective motions of fingers as predetermined motion signals; and
a motion-signal processing unit which outputs the motion signals, which are substantially concurrently detected, as effective signals having specific functions.

15. The apparatus of claim 14, wherein the motion-signal processing unit recognizes that the motion signals are substantially concurrently detected, when a first effective motion signal is detected at a first finger, and then a second effective motion signal is detected from at least one of the remaining fingers within a motion-signal detection period for a predetermined duration.

16. The apparatus of claim 15, wherein the first and second effective motion signals are detected when the motion signals exceed a critical value, and
wherein the predetermined duration is a duration for which the effective motion signals are continuously detected.

17. The apparatus of claim 16, wherein the predetermined duration is within a range of 50 ms to 100 ms when the motion-signal detection period is 200 ms.

18. The apparatus of claim 14, wherein the motion detecting unit comprises acceleration sensors for detecting variations of acceleration at said fingers.

19. The apparatus of claim 14, wherein the motion-signal processing unit comprises:
a regularizing unit which regularizes the motion signals depending on motion characteristics of each of the fingers;
an Analog-to-Digital (A/D) converting unit which converts the regularized motion signals into digital motion signals;
an effective-signal deciding unit which decides a signal having a value greater than a critical value, among the converted motion signals, as an effective motion signal; and
a signal recognizing unit which recognizes that a first and a second motion signal are substantially concurrently detected, when an effective signal of the first motion signal is detected and then, at least one effective signal of the second motion signal is detected for a predetermined duration less than a maintenance duration of the effective signal of the first motion signal.

20. The apparatus of claim 19, wherein the effective-signal deciding unit samples the converted motion signals every sampling period, and allocates a bit of ‘1’ when a magnitude of a sampled signal is greater than the critical value, and allocates a bit of ‘0’ when the magnitude is not greater than the critical value.

21. The apparatus of claim 19, wherein the signal recognizing unit comprises a memory unit which stores information on whether there is the effective signal of the first motion signal and the second motion signal, every motion signal and every sampling period, for a predetermined duration starting from the time when the effective signal of the first motion signal is detected, and
wherein the signal recognizing unit outputs the stored information as a data stream representing a specific function after the predetermined duration expires.

22. A spatial information input method comprising:
detecting respective motions of fingers of a body as predetermined motion signals;
regularizing the motion signals depending on motion characteristics of each of the fingers;
converting the regularized motion signals into digital motion signals;
deciding a signal having a value greater than a critical value, among the converted motion signals, as an effective motion signal;
recognizing that a first and a second motion signal are substantially concurrently detected, when an effective signal of the first motion signal is detected and then, at least one effective signal of the second motion signal is detected for a predetermined duration less than a maintenance duration of the effective signal of the first motion signal; and
outputting the motion signals, which are substantially concurrently detected, as effective signals having specific functions.

23. A computer-readable recording medium which records a program for executing a method comprising:
detecting respective motions of fingers of a body as predetermined motion signals;
regularizing the motion signals depending on motion characteristics of each of the fingers;
converting the regularized motion signals into digital motion signals;
deciding a signal having a value greater than a critical value, among the converted motion signals, as an effective motion signal;
recognizing that a first and a second motion signal are substantially concurrently detected, when an effective signal of the first motion signal is detected and then, at least one effective signal of the second motion signal is detected for a predetermined duration less than a maintenance duration of the effective signal of the first motion signal; and
outputting the motion signals, which are substantially concurrently detected, as effective signals having specific functions.
